(19) United States
(12) Patent Application Publication
(10) Pub. No.: US 2025/0188607 A1
(43) Pub. Date: Jun. 12, 2025

(54) METHOD OF MANUFACTURING THIN FILM

(71) Applicant: Samsung Electronics Co., Ltd., Suwon-si (KR)

(72) Inventors: Jungmin Park, Suwon-si (KR); Hanjin Lim, Suwon-si (KR); Hyungsuk Jung, Suwon-si (KR)

(21) Appl. No.: 18/782,450

(22) Filed: Jul. 24, 2024

(30) Foreign Application Priority Data
Dec. 12, 2023 (KR) 10-2023-0180096

(51) Int. Cl. C23C 16/455; C23C 16/40; C23C 16/44; H01L 21/02

(52) U.S. Cl. CPC C23C 16/45527; C23C 16/40; C23C 16/4408; H01L 21/02181; H01L 21/02189; H01L 21/0228

(57) ABSTRACT

A method of manufacturing a thin film includes an operation of providing a substrate, a first cycle including an operation of forming a first atomic layer on the substrate by using an atomic layer deposition (ALD) process using a first precursor, and a second cycle including an operation of forming a second atomic layer on the first atomic layer by using an ALD process using the first precursor and a second precursor, wherein the first atomic layer includes a ferroelectric material layer or an anti-ferroelectric material layer, the first precursor includes a first central ion, the second precursor includes a second central ion, and the second central ion is included as a substitutional ion in a lattice including the first central ion, in the second atomic layer.

### CROSS-REFERENCE TO RELATED APPLICATION

This application is based on and claims priority under 35 U.S.C. § 119 to Korean Patent Application No. 10-2023-0180096, filed on Dec. 12, 2023, in the Korean Intellectual Property Office, the disclosure of which is incorporated by reference herein in its entirety.

### BACKGROUND

Aspects of the inventive concept relate to a method of manufacturing a thin film.

In a semiconductor manufacturing process, thin film deposition denotes a process of forming a conductive material, an insulating material, and a semiconductor material on a wafer. A thin film deposition process may include an atomic layer deposition (ALD) process and a chemical vapor deposition (CVD) process. The ALD process may be a process of depositing atoms layer-by-layer and may be used when a fining process is required.

### SUMMARY

Aspects of the inventive concept provide an improved method of manufacturing a thin film.

The object of the inventive concept is not limited to the aforesaid, and other objects not described herein will be clearly understood by those of ordinary skill in the art from descriptions below.

A method of manufacturing a thin film according to an embodiment includes an operation of providing a substrate, a first cycle including an operation of forming a first atomic layer on the substrate by using an atomic layer deposition (ALD) process using a first precursor, and a second cycle including an operation of forming a second atomic layer on the first atomic layer by using an ALD process using the first precursor and a second precursor, wherein the first atomic layer includes a ferroelectric material layer or an anti-ferroelectric material layer, the first precursor includes a first central ion, the second precursor includes a second central ion, and the second central ion is included as a substitutional ion in a lattice including the first central ion, in the second atomic layer.

A method of manufacturing a thin film according to an embodiment includes an operation of providing a substrate, a first cycle including an operation of forming a first atomic layer on the substrate by using an atomic layer deposition (ALD) process using a first precursor, and a second cycle including an operation of forming a second atomic layer on the first atomic layer by using an ALD process using the first precursor and a second precursor, wherein the first atomic layer includes a ferroelectric material layer or an anti-ferroelectric material layer, the first precursor includes a first central ion, the second precursor includes a second central ion, and the second central ion is included as an interstitial ion in a lattice including the first central ion, in the second atomic layer.

A method of manufacturing a thin film according to an embodiment includes a first cycle using an atomic layer deposition (ALD) process and including an operation of supplying a first precursor, an operation of performing purging, and an operation of supplying an oxidant and a second cycle using an ALD process and including an operation of supplying a second precursor, an operation of performing purging, and an operation of supplying the oxidant, wherein the first precursor includes a first central ion, the second precursor includes a second central ion, and the first central ion includes one of a hafnium (Hf) ion and a zirconium (Zr) ion, and the second central ion is included as at least one, selected from among an interstitial ion and a substitutional ion, in a lattice including the first central ion.

### BRIEF DESCRIPTION OF THE DRAWINGS

Embodiments will be more clearly understood from the following detailed description taken in conjunction with the accompanying drawings in which:

FIG. 1 is a flowchart illustrating a method of manufacturing a thin film, according to an embodiment;

FIG. 2A is a diagram for describing a first cycle of a method of manufacturing a thin film, according to an embodiment;

FIG. 2B is a diagram schematically illustrating a first atomic layer formed by the method of manufacturing the thin film illustrated in FIG. 2A;

FIG. 3A is a diagram for describing a first cycle and a second cycle of a method of manufacturing a thin film, according to an embodiment;

FIG. 3B is a diagram schematically illustrating a second atomic layer formed by the method of manufacturing the thin film illustrated in FIG. 3A;

FIGS. 3C and 3D are diagrams for describing a first cycle and a second cycle of a method of manufacturing a thin film, according to other embodiments;

FIG. 4A is a diagram for describing a first cycle and a second cycle of a method of manufacturing a thin film, according to an embodiment;

FIG. 4B is a diagram schematically illustrating a second atomic layer formed by the method of manufacturing the thin film illustrated in FIG. 4A;

FIGS. 4C and 4D are diagrams for describing a first cycle and a second cycle of a method of manufacturing a thin film, according to other embodiments;

FIG. 5A is a diagram for describing a first cycle and a third cycle of a method of manufacturing a thin film, according to an embodiment;

FIG. 5B is a diagram schematically illustrating a third atomic layer formed by the method of manufacturing the thin film illustrated in FIG. 5A;

FIG. 5C is a diagram for describing a first cycle and a third cycle of a method of manufacturing a thin film, according to another embodiment;

FIG. 6A is a diagram for describing a first cycle and a fourth cycle of a method of manufacturing a thin film, according to an embodiment;

FIG. 6B is a diagram schematically illustrating a fourth atomic layer formed by the method of manufacturing the thin film illustrated in FIG. 6A;

FIG. 6C is a diagram for describing a first cycle and a fourth cycle of a method of manufacturing a thin film, according to another embodiment;

FIG. 7A is a diagram for describing a first cycle and a fourth cycle of a method of manufacturing a thin film, according to an embodiment;

FIG. 7B is a diagram schematically illustrating a fourth atomic layer formed by the method of manufacturing the thin film illustrated in FIG. 7A;

FIG. 7C is a diagram for describing a first cycle and a fourth cycle of a method of manufacturing a thin film, according to another embodiment;

FIG. 8A is a diagram for describing a first cycle and a fourth cycle of a method of manufacturing a thin film, according to an embodiment;

FIG. 8B is a diagram schematically illustrating a fourth atomic layer formed by the method of manufacturing the thin film illustrated in FIG. 8A;

FIG. 9 is a cross-sectional view illustrating a semiconductor device according to an embodiment;

FIG. 10 is an enlarged cross-sectional view of a region CX1 of FIG. 9;

FIG. 11 is a layout of a semiconductor device according to an embodiment;

FIG. 12 is a cross-sectional view taken along line A-A of FIG. 11; and

FIG. 13 is an enlarged cross-sectional view of a region CX2 of FIG. 12.

### DETAILED DESCRIPTION OF THE EMBODIMENTS

Hereinafter, embodiments will be described in detail with reference to the accompanying drawings. Like reference numerals refer to like elements in the drawings, and their repeated descriptions are omitted.

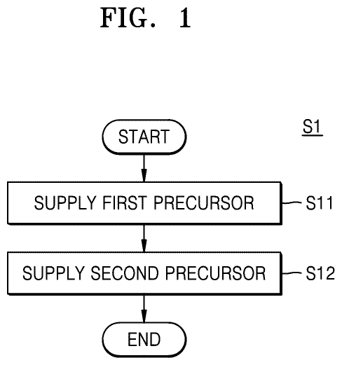

FIG. 1 is a flowchart illustrating a method S1 of manufacturing a thin film, according to an embodiment.

Referring to FIG. 1, operation S11 of supplying a first precursor may be performed, and then, operation S12 of supplying a second precursor may be performed.

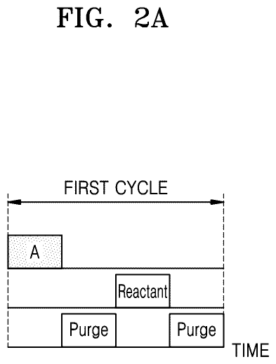

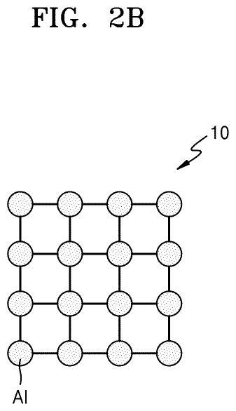

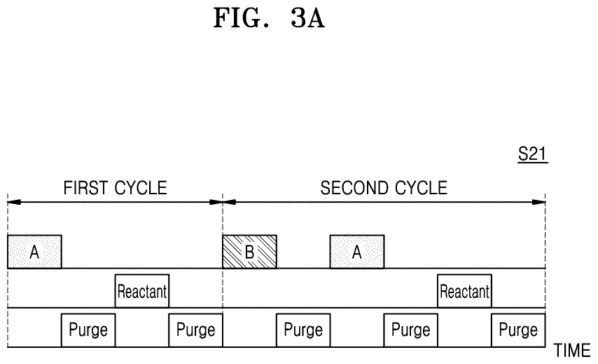

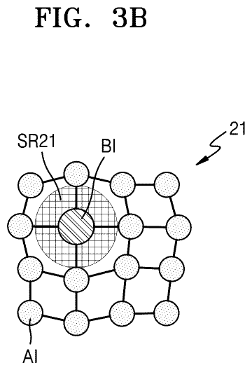

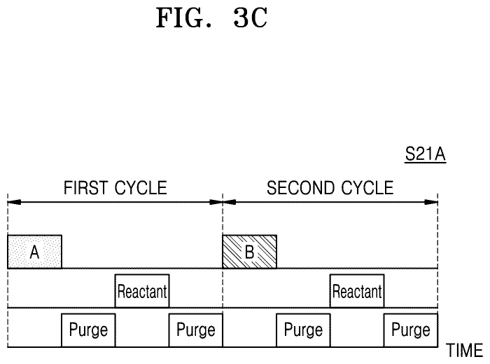

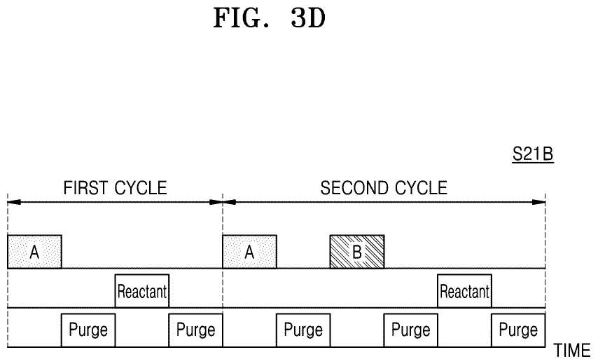

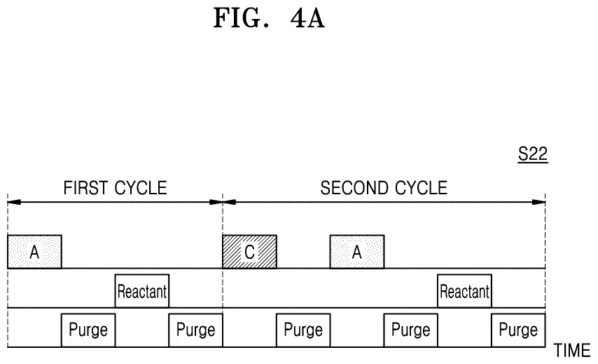

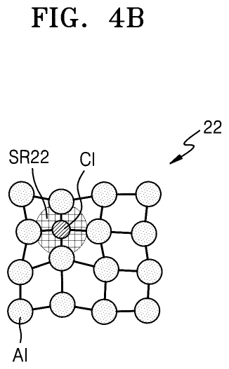

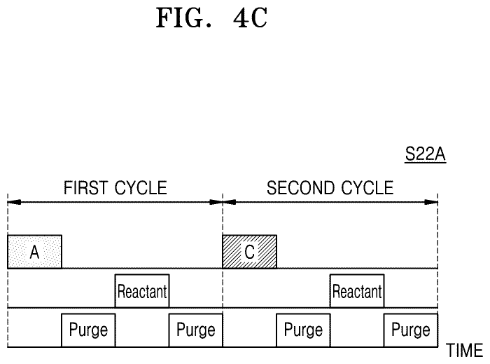

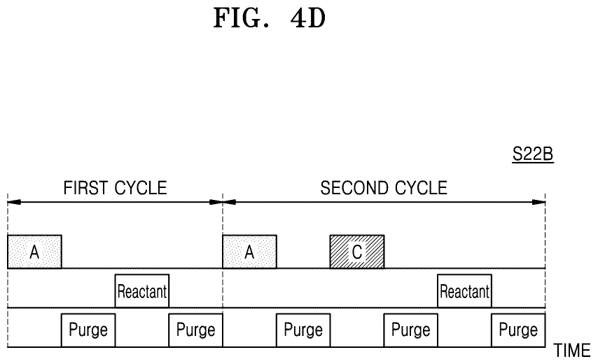

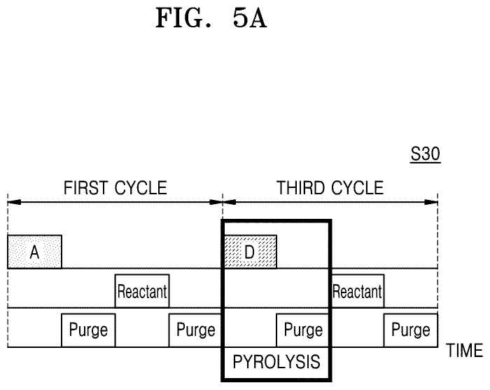

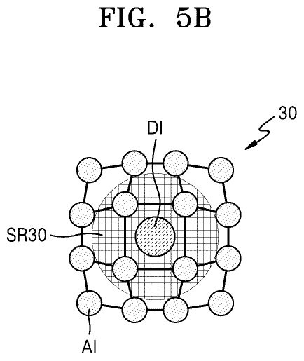

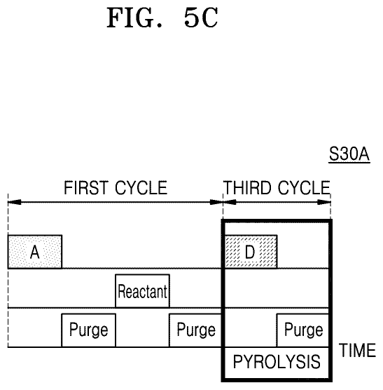

Herein, the first precursor supplied in the operation S11 of supplying the first precursor may denote a first precursor A (see FIGS. 2A and 2B and the following drawings). Herein, the second precursor supplied in the operation S12 of supplying the second precursor may denote a precursor supplied subsequent to the first precursor A. For example, the second precursor supplied in the operation S12 of supplying the second precursor may denote a second precursor B (see FIGS. 3A to 3D), a third precursor C (see FIGS. 4A to 4D), and/or a fourth precursor D (see FIGS. 5A to 5D).

That is, the method S1 of manufacturing the thin film according to an embodiment may include an operation of supplying the first precursor A and an operation of supplying the second precursor B, the third precursor C, and/or the fourth precursor D subsequent thereto. An embodiment will be described below in detail with reference to the following drawings.

FIG. 2A is a diagram for describing a first cycle of a method of manufacturing a thin film, according to an embodiment. FIG. 2B is a diagram schematically illustrating a first atomic layer 10 formed by the method of manufacturing the thin film illustrated in FIG. 2A.

Referring to FIGS. 2A and 2B, the first atomic layer 10 may be formed by an atomic layer deposition (ALD) process using a first precursor A.

In some embodiments, the first atomic layer 10 may include a ferroelectric material layer or an anti-ferroelectric material layer. For example, the first atomic layer 10 may include a perovskite material layer. For example, the first atomic layer 10 may include HfO₂, ZrO₂, SrTiO₃, HfZrO₂, PbTiO₃, AgNbO₃, Ta₂O₃, BaTiO₃, BiFeO₃, or a combination thereof, but is not limited thereto. For example, the first atomic layer 10 may include an oxide semiconductor such as indium gallium zinc oxide (IGZO).

In some embodiments, the first precursor A may include a hafnium (Hf) ion and/or a zirconium (Zr) ion as a central ion.

As illustrated in FIG. 2A, a first cycle of the method of manufacturing the thin film may include an operation of supplying the first precursor A into a process chamber where a substrate is provided. The first precursor A may be adsorbed onto the substrate. The first precursor A may include, for example, a Hf ion.

Subsequently, a reactant may be supplied into the process chamber to react with the first precursor A, and thus, the first atomic layer 10 may be formed. The reactant may be an oxidant such as ozone (O₃). As the first precursor A reacts with the reactant, the first atomic layer 10 may be deposited on a substrate. The first atomic layer 10 may include, for example, HfO₂, but is not limited thereto.

The first cycle may further include an operation of supplying a purge gas to remove a gas remaining in the process chamber, before and after an operation of supplying the first precursor A and the reactant. The purge gas may be, for example, a N₂ gas, a helium (He) gas, or an argon (Ar) gas, but is not limited thereto.

As illustrated in FIG. 2B, the first atomic layer 10 consisting of a first central ion AI of the first precursor A may be formed by the first cycle. The first central ion AI may configure a lattice configuring the first atomic layer 10. FIG. 2B schematically illustrates only the first central ion AI configuring a lattice structure of the first atomic layer 10, but aspects of the inventive concept are not limited thereto. For example, the first atomic layer 10 may further include another atom (for example, an oxygen atom (i.e., an oxygen ion)), in addition to the first central ion AI.

In some embodiments, the first cycle may be performed at a temperature of about 350° C. or less. For example, the first cycle may be performed at a temperature of about 300° C. or more or a temperature of about 350° C. or less. The first precursor A may not be pyrolyzed and may be used to form the first atomic layer 10 through an ALD process, at a temperature of about 300° C. or more or a temperature of about 350° C. or less at which the first cycle is performed.

FIG. 3A is a diagram for describing a first cycle and a second cycle of a method S21 of manufacturing a thin film, according to an embodiment. FIG. 3B is a diagram schematically illustrating a second atomic layer 21 formed by the method S21 of manufacturing the thin film illustrated in FIG. 3A. FIGS. 3C and 3D are diagrams for describing a method S21A and S21B of manufacturing a thin film, according to other embodiments.

Referring to FIGS. 3A and 3B, the second atomic layer 21 may be formed by the method S21 of manufacturing the thin film by using an ALD process using a first precursor A and a second precursor B.

As illustrated in FIG. 3A, a first cycle of supplying the first precursor A may be performed. The first atomic layer 10 (see FIGS. 2A and 2B) may be formed by the first cycle. Descriptions of the first cycle and the first atomic layer 10 may refer to FIGS. 2A and 2B and the descriptions thereof.

Subsequently, a second cycle of supplying the first precursor A and the second precursor B may be performed. The second cycle may include an operation of supplying the first precursor A and the second precursor B. In detail, the second precursor B may be supplied, and then, the first precursor A may be supplied. The first precursor A and the second precursor B may be adsorbed onto the first atomic layer 10.

In some embodiments, the second precursor B may include a material including a cyclopentadienly ligand.

In some embodiments, a size of a second central ion BI of the second precursor B may be greater than or equal to that of a first central ion AI of the first precursor A. For example, when the first central ion AI includes a Hf ion, a size of the second central ion BI may be about 0.7 Å or more. For example, when the first central ion AI includes a Zr ion, a size of the second central ion BI may be about 0.7 Å or more. For example, the second central ion BI may differ from the first central ion AI and may include one ion selected from among a Ta⁺³ ion, a Mn⁺² ion, a V⁺² ion, a Nb⁺³ ion, a Sr⁺² ion, a Ba⁺² ion, a Ca⁺² ion, a Y⁺³ ion, a Sc⁺³ ion, a Cr⁺² ion, a Hf⁴ ion, a Zr⁺⁴ ion, and a Co⁺² ion.

Subsequently, a reactant may be supplied into the process chamber to react with the first precursor A and the second precursor B, and thus, the second atomic layer 21 may be formed.

The second cycle may further include an operation of supplying a purge gas to remove a gas remaining in the process chamber, before and after an operation of supplying the first precursor A, the second precursor B, and the reactant. The purge gas may be, for example, a N₂ gas, a He gas, or an Ar gas, but is not limited thereto.

In some embodiments, the second cycle may be performed at a temperature of about 350° C. or less. For example, the second cycle may be performed at a temperature of about 300° C. or more or a temperature of about 350° C. or less. The second precursor B may not be pyrolyzed and may be used to form the second atomic layer 21 through an ALD process, at a temperature of about 300° C. or more or a temperature of about 350° C. or less at which the second cycle is performed.

As illustrated in FIG. 3B, the second atomic layer 21 configured with the first central ion AI of the first precursor A and the second central ion BI of the second precursor B may be formed by the second cycle. In detail, the second central ion BI may be included as a substitutional ion in a lattice consisting of the first central ion AI.

In some embodiments, when the second central ion BI having a relatively larger size is included as a substitutional ion in the lattice consisting of the first central ion AI, a strained region may be formed in the lattice. For example, the second atomic layer 21 may include a strained region SR21 which is formed around a substituted second central ion BI. Because a lattice of the second atomic layer 21 includes the strained region SR21, the distortion of the lattice may occur. Accordingly, stress may be applied to a lattice, and thus, a ferroelectric characteristic and/or an anti-ferroelectric characteristic of a material layer may be enhanced.

In other words, by the method S21 of manufacturing the thin film according to an embodiment, the second atomic layer 21 whose ferroelectric characteristic and/or an anti-ferroelectric characteristic of a material layer are/is enhanced may be formed. That is, by the method S21 of manufacturing the thin film according to an embodiment, the second atomic layer 21 whose dielectric performance is enhanced may be formed.

Referring to FIG. 3C, the method S21A of manufacturing the thin film according to an embodiment may include a first cycle of supplying a first precursor A and a second cycle of supplying a second precursor B. The method S21A of manufacturing the thin film may include an ALD process using the first precursor A and the second precursor B. Each of the first cycle and the second cycle may further include an operation of supplying a purge gas to remove a gas remaining in the process chamber, before and after a process of supplying the first precursor A, the second precursor B, and a reactant.

Based on the method S21A of manufacturing the thin film, an atomic layer including a central ion of the first precursor A and a central ion of the second precursor B may be formed. In detail, in the atomic layer, the central ion of the second precursor B may be included as a substitutional ion in a lattice consisting of the central ion of the first precursor A.

Referring to FIG. 3D, the method S21B of manufacturing the thin film according to an embodiment may include a first cycle of supplying a first precursor A and a second cycle of supplying the first precursor A and a second precursor B. The method S21B of manufacturing the thin film may include an ALD process using the first precursor A and the second precursor B. In the second cycle, the first precursor A may be supplied, and then, the second precursor B may be supplied. Each of the first cycle and the second cycle may further include an operation of supplying a purge gas to remove a gas remaining in the process chamber, before and after a process of supplying the first precursor A, the second precursor B, and a reactant.

Based on the method S21B of manufacturing the thin film, an atomic layer including a central ion of the first precursor A and a central ion of the second precursor B may be formed. In detail, in the atomic layer, the central ion of the second precursor B may be included as a substitutional ion in a lattice consisting of the central ion of the first precursor A.

FIG. 4A is a diagram for describing a first cycle and a second cycle of a method S22 of manufacturing a thin film, according to an embodiment. FIG. 4B is a diagram schematically illustrating a second atomic layer 22 formed by the method S22 of manufacturing the thin film illustrated in FIG. 4A. FIGS. 4C and 4D are diagrams for describing a method S22A and S22B of manufacturing a thin film, according to other embodiments.

Referring to FIGS. 4A and 4B, the second atomic layer 22 may be formed by the method S22 of manufacturing the thin film by using an ALD process using a first precursor A and a third precursor C.

As illustrated in FIG. 4A, a first cycle of supplying the first precursor A may be performed. The first atomic layer 10 (see FIGS. 2A and 2B) may be formed by the first cycle. Descriptions of the first cycle and the first atomic layer 10 may refer to FIGS. 2A and 2B and the descriptions thereof.

Subsequently, a second cycle of supplying the first precursor A and the third precursor C may be performed. The second cycle may include an operation of supplying the first precursor A and the third precursor C. In detail, the third precursor C may be supplied, and then, the first precursor A may be supplied. The first precursor A and the third precursor C may be adsorbed onto the first atomic layer 10.

In some embodiments, the third precursor C may include a material including a cyclopentadienly ligand.

In some embodiments, a size of a third central ion CI of the third precursor C may be less than that of a first central ion AI of the first precursor A. For example, when the first central ion AI includes a Hf ion, a size of the third central ion CI may be less than about 0.7 Å. For example, when the first central ion AI includes a Zr ion, a size of the third central ion CI may be less than about 0.7 Å. For example, the third central ion CI may differ from the first central ion AI and may include one ion selected from among a Ti⁺³ ion, a Ni⁺³ ion, a Si⁺⁴ ion, an Al⁺³ ion, and a Be⁺² ion.

Subsequently, a reactant may be supplied into the process chamber to react with the first precursor A and the third precursor C, and thus, the second atomic layer 22 may be formed.

The second cycle may further include an operation of supplying a purge gas to remove a gas remaining in the process chamber, before and after an operation of supplying the first precursor A, the third precursor C, and the reactant.

In some embodiments, the second cycle may be performed at a temperature of about 350° C. or less. For example, the second cycle may be performed at a temperature of about 300° C. or more or a temperature of about 350° C. or less. The third precursor C may not be pyrolyzed and may be used to form the second atomic layer 22 through an ALD process, at a temperature of about 300° C. or more or a temperature of about 350° C. or less at which the second cycle is performed.

As illustrated in FIG. 4B, the second atomic layer 22 including the first central ion AI of the first precursor A and the third central ion CI of the third precursor C may be formed by the second cycle. In detail, the third central ion CI may be included as a substitutional ion in a lattice consisting of the first central ion AI.

In some embodiments, when the third central ion CI having a relatively smaller size is included as a substitutional ion in the lattice consisting of the first central ion AI, a strained region may be formed in the lattice. For example, the second atomic layer 22 may include a strained region SR22 which is formed around a substituted third central ion CI. Because a lattice of the second atomic layer 22 includes the strained region SR22, the distortion of the lattice may occur. Accordingly, stress may be applied to a lattice, and thus, a ferroelectric characteristic and/or an anti-ferroelectric characteristic of a material layer may be enhanced.

In other words, based on the method S22 of manufacturing the thin film according to an embodiment, the second atomic layer 22 whose a ferroelectric characteristic and/or an anti-ferroelectric characteristic of a material layer are/is enhanced may be formed. That is, based on the method S22 of manufacturing the thin film according to an embodiment, the second atomic layer 22 whose dielectric performance is enhanced may be formed.

Referring to FIG. 4C, the method S22A of manufacturing the thin film according to an embodiment may include a first cycle of supplying a first precursor A and a second cycle of supplying a third precursor C. The method S22A of manufacturing the thin film may include an ALD process using the first precursor A and the third precursor C. Each of the first cycle and the second cycle may further include an operation of supplying a purge gas to remove a gas remaining in the process chamber, before and after a process of supplying the first precursor A, the third precursor C, and a reactant.

Based on the method S21A of manufacturing the thin film, an atomic layer including a central ion of the first precursor A and a central ion of the third precursor C may be formed. In detail, in the atomic layer, the central ion of the third precursor C may be included as a substitutional ion in a lattice consisting of the central ion of the first precursor A.

Referring to FIG. 4D, the method S22B of manufacturing the thin film according to an embodiment may include a first cycle of supplying a first precursor A and a second cycle of supplying the first precursor A and a third precursor C. The method S22B of manufacturing the thin film may include an ALD process using the first precursor A and the third precursor C. In the second cycle, the first precursor A may be supplied, and then, the third precursor C may be supplied. Each of the first cycle and the second cycle may further include an operation of supplying a purge gas to remove a gas remaining in the process chamber, before and after a process of supplying the first precursor A, the third precursor C, and a reactant.

Based on the method S22B of manufacturing the thin film, an atomic layer including a central ion of the first precursor A and a central ion of the third precursor C may be formed. In detail, in the atomic layer, the central ion of the third precursor C may be included as a substitutional ion in a lattice consisting of the central ion of the first precursor A.

FIG. 5A is a diagram for describing a first cycle and a third cycle of a method S30 of manufacturing a thin film, according to an embodiment. FIG. 5B is a diagram schematically illustrating a third atomic layer 30 formed by the method S30 of manufacturing the thin film illustrated in FIG. 5A. FIG. 5C is a diagram for describing a method S30A of manufacturing a thin film, according to another embodiment.

Referring to FIGS. 5A and 5B, the third atomic layer 30 may be formed by the method S30 of manufacturing the thin film by using an ALD process using a first precursor A and a fourth precursor D. In detail, the method S30 of manufacturing the thin film may form the third atomic layer 30 by using an ALD process using the first precursor A.

As illustrated in FIG. 5A, a first cycle of supplying the first precursor A may be performed. The first atomic layer 10 (see FIGS. 2A and 2B) may be formed by the first cycle. Descriptions of the first cycle and the first atomic layer 10 may refer to FIGS. 2A and 2B and the descriptions thereof.

Subsequently, a third cycle of supplying the fourth precursor D may be performed. The third cycle may include an operation of supplying the fourth precursor D and an operation of supplying a reactant.

In some embodiments, the fourth precursor D may include a material including an amine ligand.

In some embodiments, a size of a fourth central ion DI of the fourth precursor D may be greater than or equal to that of a first central ion AI of the first precursor A. For example, when the first central ion AI includes a Hf ion, a size of the fourth central ion DI may be about 0.7 Å or more. For example, when the first central ion AI includes a Zr ion, a size of the fourth central ion DI may be about 0.7 Å or more. For example, the fourth central ion DI may differ from the first central ion AI and may include one ion selected from among a Ta⁺³ ion, a Mn⁺² ion, a V⁺² ion, a Nb⁺³ ion, a Sr⁺² ion, a Ba⁺² ion, a Ca⁺² ion, a Y⁺³ ion, a Sc⁺³ ion, a Cr⁺² ion, a Hf⁺⁴ ion, a Zr⁺⁴ ion, and a Co⁺² ion.

Each of the first cycle and the third cycle may further include an operation of supplying a purge gas to remove a gas remaining in the process chamber, before and after a process of supplying the first precursor A, the fourth precursor D, and a reactant. The purge gas may be, for example, a N₂ gas, a He gas, or an Ar gas, but is not limited thereto.

In some embodiments, the first cycle and the third cycle may be performed at a temperature of about 350° C. or less. For example, the first cycle and the third cycle may be performed at a temperature of about 300° C. or more or a temperature of about 350° C. or less. The fourth precursor D may be pyrolyzed at a temperature of about 300° C. or more or a temperature of about 350° C. or less at which the third cycle is performed. For example, the third cycle may include a period where the fourth precursor D is pyrolyzed. In detail, in the third cycle, the fourth precursor D may be pyrolyzed and may invade into the first atomic layer 10 formed by the first cycle, instead of forming an atomic layer through an ALD process. Accordingly, the third atomic layer 30 may be formed.

As illustrated in FIG. 5B, the third atomic layer 30 including the first central ion AI of the first precursor A and the fourth central ion DI of the fourth precursor D may be formed by the first cycle and the third cycle. In detail, the fourth central ion DI may be pyrolyzed and may be included as an interstitial ion in a lattice consisting of the first central ion AI.

In some embodiments, a composition ratio of the fourth central ion DI of the fourth precursor D in the third atomic layer 30 may be about 30 at % or less.

In some embodiments, when the fourth central ion DI having a relatively larger size is included as an interstitial ion in the lattice consisting of the first central ion AI, a strained region may be formed in the lattice. For example, the third atomic layer 30 may include a strained region SR30 which is formed around an interstitial fourth central ion DI. Because a lattice of the third atomic layer 30 includes the strained region SR30, the distortion of the lattice may occur. Accordingly, stress may be applied to a lattice, and thus, a ferroelectric characteristic and/or an anti-ferroelectric characteristic of a material layer may be enhanced.

In other words, based on the method S30 of manufacturing the thin film according to an embodiment, the third atomic layer 30 whose a ferroelectric characteristic and/or an anti-ferroelectric characteristic of a material layer are/is enhanced may be formed. That is, based on the method S30 of manufacturing the thin film according to an embodiment, the third atomic layer 30 whose dielectric performance is enhanced may be formed.

Referring to FIG. 5C, the method S30A of manufacturing the thin film according to an embodiment may include a first cycle of supplying a first precursor A and a third cycle of supplying a fourth precursor D. The method S30A of manufacturing the thin film may include an ALD process using the first precursor A. The third cycle may include a period where the fourth precursor D is pyrolyzed. Each of the first cycle and the third cycle may further include an operation of supplying a purge gas to remove a gas remaining in the process chamber, before and after a process of supplying the first precursor A, the fourth precursor D, and a reactant.

Based on the method S30A of manufacturing the thin film, An atomic layer including a central ion of the first precursor A and a central ion of the fourth precursor D may be formed. In detail, in the atomic layer, the central ion of the fourth precursor D may be included as an interstitial ion in a lattice consisting of the central ion of the first precursor A. In detail, the fourth precursor D may be pyrolyzed and may invade into the first atomic layer 10.

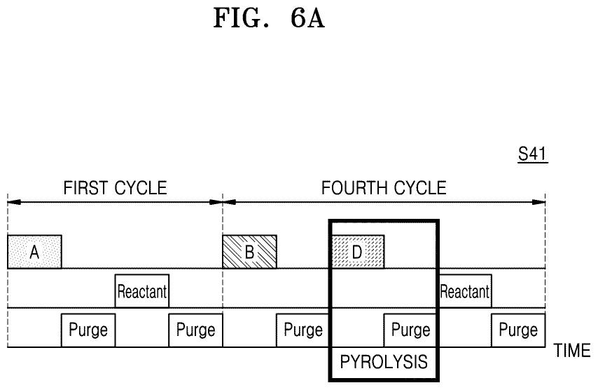

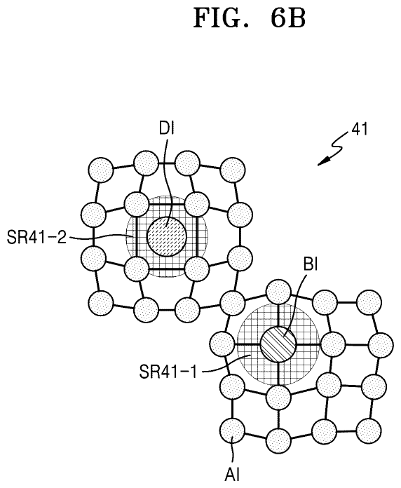

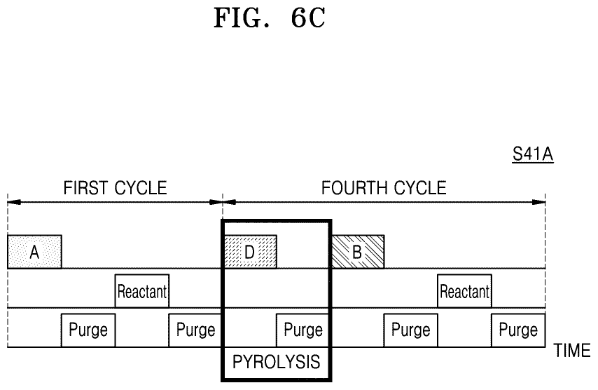

FIG. 6A is a diagram for describing a first cycle and a fourth cycle of a method S41 of manufacturing a thin film, according to an embodiment. FIG. 6B is a diagram schematically illustrating a fourth atomic layer 41 formed by the method S41 of manufacturing the thin film illustrated in FIG. 6A. FIG. 6C is a diagram for describing a method S41A of manufacturing a thin film, according to another embodiment.

Referring to FIGS. 6A and 6B, the fourth atomic layer 41 may be formed by the method S41 of manufacturing the thin film by using an ALD process using a first precursor A, a second precursor B, and a fourth precursor D.

As illustrated in FIG. 6A, a first cycle of supplying the first precursor A may be performed. The first atomic layer 10 (see FIGS. 2A and 2B) may be formed by the first cycle. Descriptions of the first cycle and the first atomic layer 10 may refer to FIGS. 2A and 2B and the descriptions thereof.

Subsequently, a fourth cycle of supplying the second precursor B and the fourth precursor D may be performed. The fourth cycle may include an operation of supplying the second precursor B and the fourth precursor D. In detail, the second precursor B may be supplied, and then, the fourth precursor D may be supplied. Subsequently, a reactant may be supplied.

The fourth cycle may further include an operation of supplying a purge gas to remove a gas remaining in the process chamber, before and after an operation of supplying the second precursor B, the fourth precursor D, and the reactant. The purge gas may be, for example, a N₂ gas, a helium (He) gas, or an argon (Ar) gas, but is not limited thereto.

In some embodiments, the fourth cycle may be performed at a temperature of about 350° C. or less. For example, the fourth cycle may be performed at a temperature of about 300° C. or more or a temperature of about 350° C. or less. In the fourth cycle, the second precursor B may not be pyrolyzed and may be used to form the fourth atomic layer 41 through an ALD process. The fourth cycle may include a period where the fourth precursor D is pyrolyzed. In the fourth cycle, the fourth precursor D may be pyrolyzed and may invade into the first atomic layer 10 formed by the first cycle. Accordingly, the fourth atomic layer 41 may be formed.

As illustrated in FIG. 6B, the fourth atomic layer 41 including the first central ion AI of the first precursor A, a second central ion BI of the second precursor B, and the fourth central ion DI of the fourth precursor D may be formed by the first cycle and the fourth cycle. In detail, the second central ion BI may be included as a substitutional ion in a lattice consisting of the first central ion AI. In detail, the fourth central ion DI may be pyrolyzed and may be included as an interstitial ion in a lattice consisting of the first central ion AI.

In some embodiments, when the second central ion BI and the fourth central ion DI each having a relatively larger size are respectively included as a substitutional ion and an interstitial ion in the lattice consisting of the first central ion AI, a strained region may be formed in the lattice. For example, the fourth atomic layer 41 may include a strained region SR41-1 which is formed around a substituted second central ion BI. For example, the fourth atomic layer 41 may include a strained region SR41-2 which is formed around an interstitial fourth central ion DI. Because a lattice of the fourth atomic layer 41 includes the strained regions SR41-1 and SR41-2, the distortion of the lattice may occur. Accordingly, stress may be applied to a lattice, and thus, a ferroelectric characteristic and/or an anti-ferroelectric characteristic of a material layer may be enhanced.

In other words, based on the method S41 of manufacturing the thin film according to an embodiment, the fourth atomic layer 41 whose ferroelectric characteristic and/or an anti-ferroelectric characteristic of a material layer are/is enhanced may be formed. That is, based on the method S41 of manufacturing the thin film, the fourth atomic layer 41 whose dielectric performance is enhanced may be formed.

Referring to FIG. 6C, the method S41A of manufacturing the thin film according to an embodiment may include a first cycle of supplying a first precursor A and a fourth cycle of supplying the second precursor B and a fourth precursor D. The method S41A of manufacturing the thin film may include an ALD process using the first precursor A and the second precursor B. In the fourth cycle, the fourth precursor D may be supplied, and then, the second precursor B may be supplied. The fourth cycle may include a period where the fourth precursor D is pyrolyzed. Each of the first cycle and the fourth cycle may further include an operation of supplying a purge gas to remove a gas remaining in the process chamber, before and after a process of supplying the first precursor A, the second precursor B, the fourth precursor D, and a reactant.

Based on the method S41A of manufacturing the thin film, an atomic layer including a central ion of the first precursor A, a central ion of the second precursor B, and a central ion of the fourth precursor D may be formed. In detail, the central ion of the second precursor B may be included as a substitutional ion in a lattice consisting of the central ion of the first precursor A. In detail, the central ion of the fourth precursor D may be included as an interstitial ion in a lattice consisting of the central ion of the first precursor A.

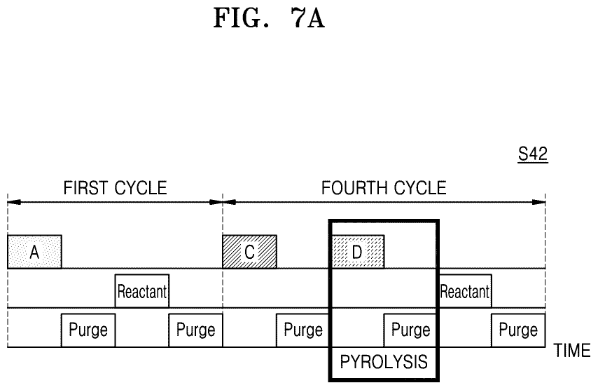

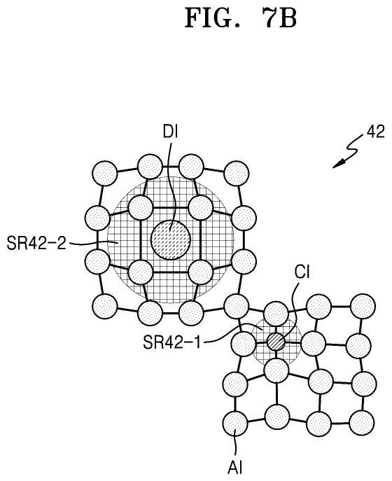

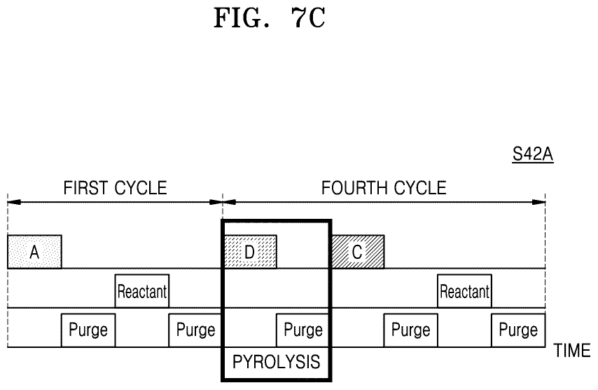

FIG. 7A is a diagram for describing a first cycle and a fourth cycle of a method S42 of manufacturing a thin film, according to an embodiment. FIG. 7B is a diagram schematically illustrating a fourth atomic layer 42 formed by the method S42 of manufacturing the thin film illustrated in FIG. 7A. FIG. 7C is a diagram for describing a method S42A of manufacturing a thin film, according to another embodiment.

Referring to FIGS. 7A and 7B, the fourth atomic layer 42 may be formed by the method S42 of manufacturing the thin film by using an ALD process using a first precursor A, a third precursor C, and a fourth precursor D.

As illustrated in FIG. 7A, a first cycle of supplying the first precursor A may be performed. The first atomic layer 10 (see FIGS. 2A and 2B) may be formed by the first cycle. Descriptions of the first cycle and the first atomic layer 10 may refer to FIGS. 2A and 2B and the descriptions thereof.

Subsequently, a fourth cycle of supplying the third precursor C and the fourth precursor D may be performed. The fourth cycle may include an operation of supplying the third precursor C and the fourth precursor D. In detail, the third precursor C may be supplied, and then, the fourth precursor D may be supplied. Subsequently, a reactant may be supplied.

The fourth cycle may further include an operation of supplying a purge gas to remove a gas remaining in the process chamber, before and after an operation of supplying the third precursor C, the fourth precursor D, and the reactant.

In some embodiments, the fourth cycle may be performed at a temperature of about 350° C. or less. For example, the fourth cycle may be performed at a temperature of about 300° C. or more or a temperature of about 350° C. or less. In the fourth cycle, the third precursor C may not be pyrolyzed and may be used to form the fourth atomic layer 42 through an ALD process. The fourth cycle may include a period where the fourth precursor D is pyrolyzed. In the fourth cycle, the fourth precursor D may be pyrolyzed and may invade into the first atomic layer 10 formed by the first cycle. Accordingly, the fourth atomic layer 42 may be formed.

As illustrated in FIG. 7B, the fourth atomic layer 42 including a first central ion AI of the first precursor A, a third central ion CI of the third precursor C, and a fourth central ion DI of the fourth precursor D may be formed by the first cycle and the fourth cycle. In detail, the third central ion CI may be included as a substitutional ion in a lattice consisting of the first central ion AI. In detail, the fourth central ion DI may be pyrolyzed and may be included as an interstitial ion in a lattice consisting of the first central ion AI.

In some embodiments, when the third central ion CI having a relatively smaller size and the fourth central ion DI having a relatively larger size are respectively included as a substitutional ion and an interstitial ion in the lattice consisting of the first central ion AI, a strained region may be formed in the lattice. For example, the fourth atomic layer 42 may include a strained region SR42-1 which is formed around a substituted third central ion CI. For example, the fourth atomic layer 42 may include a strained region SR42-2 which is formed around an interstitial fourth central ion DI. Because a lattice of the fourth atomic layer 42 includes the strained regions SR42-1 and SR42-2, the distortion of the lattice may occur. Accordingly, stress may be applied to a lattice, and thus, a ferroelectric characteristic and/or an anti-ferroelectric characteristic of a material layer may be enhanced.

In other words, based on the method S42 of manufacturing the thin film according to an embodiment, the fourth atomic layer 42 whose ferroelectric characteristic and/or an anti-ferroelectric characteristic of a material layer are/is enhanced may be formed. That is, based on the method S42 of manufacturing the thin film, the fourth atomic layer 42 whose dielectric performance is enhanced may be formed.

Referring to FIG. 7C, the method S42A of manufacturing the thin film according to an embodiment may include a first cycle of supplying a first precursor A and a fourth cycle of supplying a third precursor C and a fourth precursor D. The method S42A of manufacturing the thin film may include an ALD process using the first precursor A and the third precursor C. In the fourth cycle, the fourth precursor D may be supplied, and then, the third precursor C may be supplied. The fourth cycle may include a period where the fourth precursor D is pyrolyzed. Each of the first cycle and the fourth cycle may further include an operation of supplying a purge gas to remove a gas remaining in the process chamber, before and after a process of supplying the first precursor A, the third precursor C, the fourth precursor D, and a reactant.

Based on the method S42A of manufacturing the thin film, an atomic layer including a central ion of the first precursor A, a central ion of the third precursor C, and a central ion of the fourth precursor D may be formed. In detail, the central ion of the third precursor C may be included as a substitutional ion in a lattice consisting of the central ion of the first precursor A. In detail, the central ion of the fourth precursor D may be included as an interstitial ion in a lattice consisting of the central ion of the first precursor A.

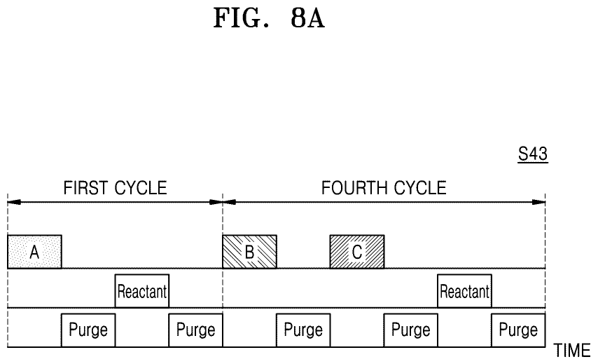

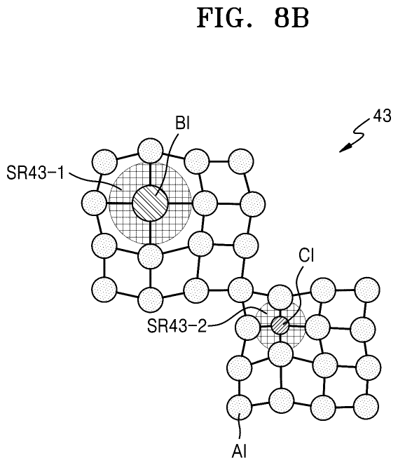

FIG. 8A is a diagram for describing a first cycle and a fourth cycle of a method S43 of manufacturing a thin film, according to an embodiment. FIG. 8B is a diagram schematically illustrating a fourth atomic layer 43 formed by the method S43 of manufacturing the thin film illustrated in FIG. 8A.

Referring to FIGS. 8A and 8B, the fourth atomic layer 43 may be formed by the method S43 of manufacturing the thin film by using an ALD process using a first precursor A, a second precursor B, and a third precursor C.

As illustrated in FIG. 8A, a first cycle of supplying the first precursor A may be performed. The first atomic layer 10 (see FIGS. 2A and 2B) may be formed by the first cycle. Descriptions of the first cycle and the first atomic layer 10 may refer to FIGS. 2A and 2B and the descriptions thereof.

Subsequently, a fourth cycle of supplying the second precursor B and the third precursor C may be performed. The fourth cycle may include an operation of supplying the second precursor B and the third precursor C. In detail, the second precursor B may be supplied, and then, the third precursor C may be supplied. Subsequently, a reactant may be supplied.

The fourth cycle may further include an operation of supplying a purge gas to remove a gas remaining in the process chamber, before and after an operation of supplying the second precursor B, the third precursor C, and the reactant.

In some embodiments, the fourth cycle may be performed at a temperature of about 350° C. or less. For example, the fourth cycle may be performed at a temperature of about 300° C. or more or a temperature of about 350° C. or less. In the fourth cycle, the second precursor B and third precursor C may not be pyrolyzed and may be used to form the fourth atomic layer 43 through an ALD process.

As illustrated in FIG. 8B, the fourth atomic layer 43 including a first central ion AI of the first precursor A, a second central ion BI of the second precursor B, and a third central ion CI of the third precursor C may be formed by the first cycle and the fourth cycle. In detail, the second central ion BI and the third central ion CI may be included as a substitutional ion in a lattice consisting of the first central ion AI.

In some embodiments, when the second central ion BI having a relatively larger size and the third central ion CI having a relatively smaller size are respectively included as a substitutional ion in the lattice consisting of the first central ion AI, a strained region may be formed in the lattice. For example, the fourth atomic layer 43 may include a strained region SR43-1 which is formed around a substituted second central ion BI. For example, the fourth atomic layer 43 may include a strained region SR43-2 which is formed around a substituted third central ion CI. Because a lattice of the fourth atomic layer 43 includes the strained regions SR43-1 and SR43-2, the distortion of the lattice may occur. Accordingly, stress may be applied to a lattice, and thus, a ferroelectric characteristic and/or an anti-ferroelectric characteristic of a material layer may be enhanced.

In other words, based on the method S43 of manufacturing the thin film according to an embodiment, the fourth atomic layer 43 whose ferroelectric characteristic and/or an anti-ferroelectric characteristic of a material layer are/is enhanced may be formed. That is, based on the method S43 of manufacturing the thin film according to an embodiment, the fourth atomic layer 43 whose dielectric performance is enhanced may be formed.

The lattice of the first atomic layer 10, second atomic layers 21 and 22, third atomic layer 30, and fourth atomic layers 41 to 43 may comprise an orthorhombic phase (e.g., system), a tetragonal phase, and a rhombohedral phase. Additionally, the lattice strain of the first atomic layer 10, second atomic layers 21 and 22, third atomic layer 30, and fourth atomic layers 41 to 43 may range from −5% to +10%. The volume strain the first atomic layer 10, second atomic layers 21 and 22, third atomic layer 30, and fourth atomic layers 41 to 43 may range from −20% to 30%.

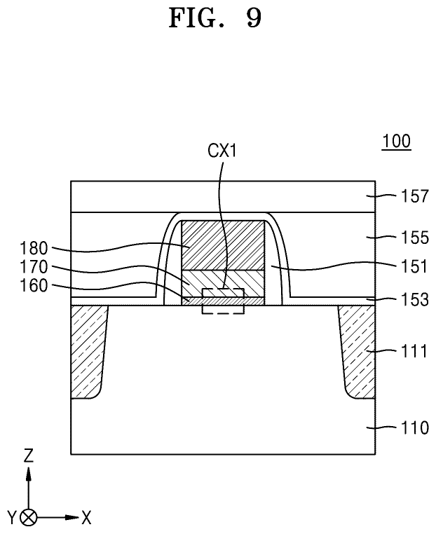

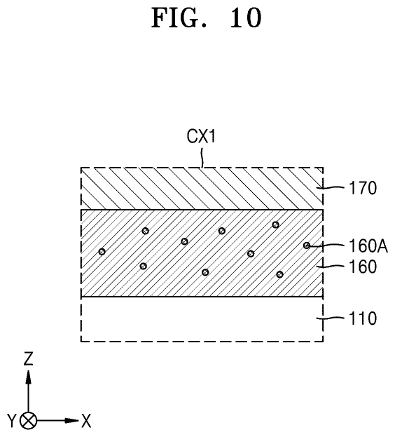

FIG. 9 is a cross-sectional view illustrating a semiconductor device 100 according to an embodiment. FIG. 10 is an enlarged cross-sectional view of a region CX1 of FIG. 9.

Referring to FIGS. 9 and 10, the semiconductor device 100 may include a transistor on a substrate 110.

In some embodiments, the substrate 110 may include, for example, silicon (Si), crystalline Si, polycrystalline Si, or amorphous Si. In some other embodiments, the substrate 110 may include a semiconductor element, such as germanium (Ge), or at least one compound semiconductor selected from among silicon germanium (SiGe), silicon carbide (SiC), gallium arsenide (GaAs), indium arsenide (InAs), and indium phosphide (InP). In some embodiments, the substrate 110 may have a silicon on insulator (SOI) structure. For example, the substrate 110 may include a buried oxide (BOX) layer. The substrate 110 may include a conductive region, and for example, may include an impurity-doped well or an impurity-doped structure.

In some embodiments, a plurality of active regions may be defined by a device isolation layer 111 in the substrate 110. The device isolation layer 111 may include a single layer or a multilayer, which includes silicon oxide and/or silicon nitride.

In some embodiments, a gate dielectric layer 160, a gate electrode 170, and a gate upper capping pattern 180 may be sequentially arranged in the active region of the substrate 110.

In some embodiments, the gate dielectric layer 160 may include a thin film which is formed by the methods S1, S21, S21A, S21B, S22, S22A, S22B, S30, S30A, S41, S41A, S42, S42A, and S43 of manufacturing the thin film described above with reference to FIGS. 1, 2A, 2B, 3A to 3D, 4A to 4D, 5A to 5C, 6A to 6C, 7A to 7C, 8A, and 8B. For example, the gate dielectric layer 160 may include a first atomic layer 10, second atomic layers 21 and 22, a third atomic layer 30, and/or fourth atomic layers 41 to 43.

In some embodiments, the gate dielectric layer 160 may include an additive ion 160A included in an atomic layer. The additive ion 160A may include one or more ions selected from among the second central ion BI, the third central ion CI, and the fourth central ion DI described above with reference to FIGS. 2A, 2B, 3A to 3D, 4A to 4D, 5A to 5C, 6A to 6C, 7A to 7C, 8A, and 8B. For example, the gate dielectric layer 160 may include a lattice consisting of the first central ion AI of the first precursor A, and the additive ion 160A may include the second central ion BI, the third central ion CI, and/or the fourth central ion DI each included in the lattice consisting of the first central ion AI. For example, the additive ion 160A may be included as a substitutional ion and/or an interstitial ion in the lattice of the gate dielectric layer 160.

In some embodiments, the gate electrode 170 may include polysilicon. The gate upper capping pattern 180 may include silicon nitride.

In some embodiments, both sidewalls of each of the gate dielectric layer 160, the gate electrode 170, and the gate upper capping pattern 180 may be covered by a spacer 151. The spacer 151 may include oxide, nitride, or a combination thereof.

In some embodiments, the gate dielectric layer 160, the gate electrode 170, the gate upper capping pattern 180, and the spacer 151 may be covered by a protection layer 153. The protection layer 153 may include silicon nitride. A first interlayer insulation layer 155 and a second interlayer insulation layer 157 may be formed on the protection layer 153. The first interlayer insulation layer 155 may include tonen silazene (TOSZ). The second interlayer insulation layer 157 may include silicon nitride.

Herein, the semiconductor device 100 including the gate dielectric layer 160, the gate electrode 170, the gate upper capping pattern 180, the spacer 151, the protection layer 153, the first interlayer insulation layer 155, and the second interlayer insulation layer 157 may be described, but aspects of the inventive concept are not limited thereto. For example, the semiconductor device 100 may include the gate dielectric layer 160, the gate electrode 170, and the spacer 151.

In some embodiments, the semiconductor device 100 may be a transistor of a peripheral circuit region of a dynamic random access memory (DRAM) device. In some other embodiments, the semiconductor device 100 may be a transistor of a peri region of a NAND flash memory device.

The gate dielectric layer 160 of the semiconductor device 100 according to an embodiment may be formed by substantially the same method as the methods S1, S21, S21A, S21B, S22, S22A, S22B, S30, S30A, S41, S41A, S42, S42A, and S43 of manufacturing the thin film described above with reference to FIGS. 1, 2A, 2B, 3A to 3D, 4A to 4D, 5A to 5C, 6A to 6C, 7A to 7C, 8A, and 8B.

The semiconductor device 100 according to an embodiment may include the additive ion 160A which is included as a substitutional ion and/or an interstitial ion in the lattice of the gate dielectric layer 160, and accordingly, stress may be applied to the lattice of the gate dielectric layer 160, thereby enhancing a ferroelectric characteristic and/or an anti-ferroelectric characteristic of the gate dielectric layer 160. Accordingly, the performance of the semiconductor device 100 may be enhanced.

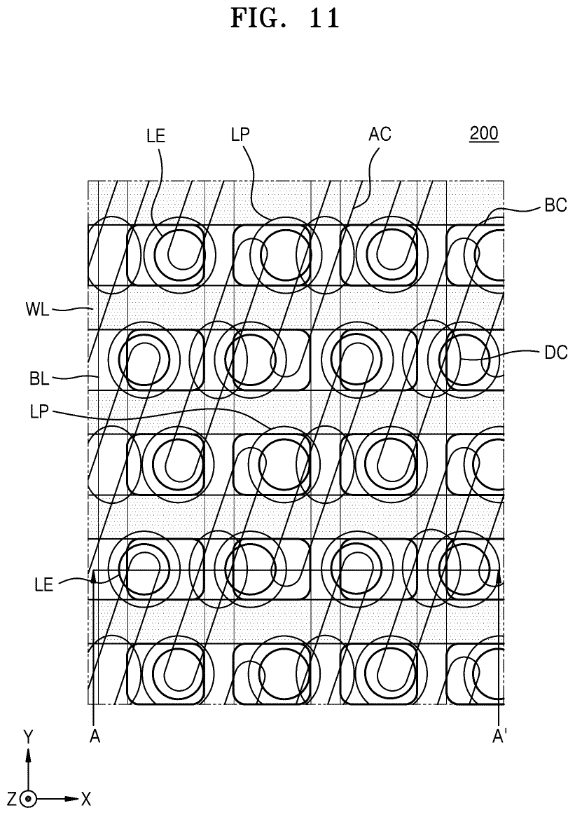

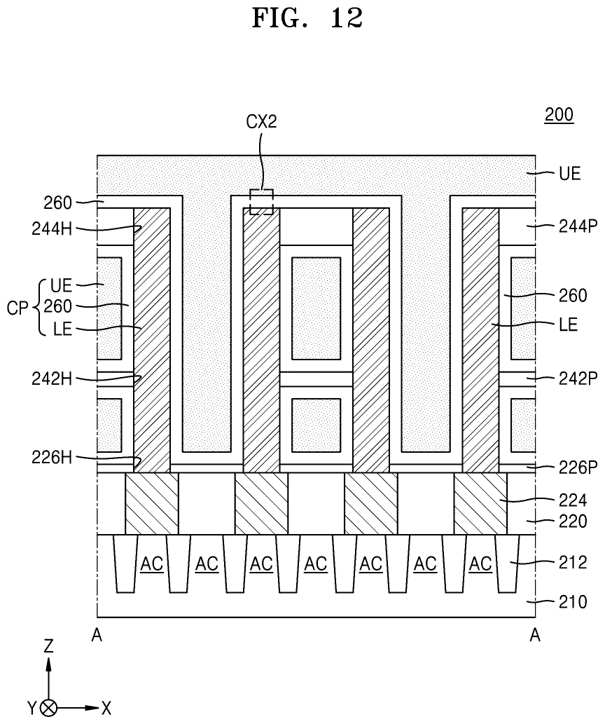

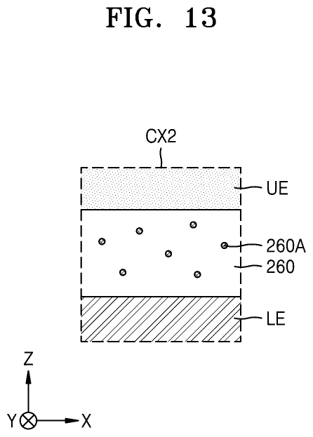

FIG. 11 is a layout illustrating a semiconductor device 200 according to an embodiment. FIG. 12 is a cross-sectional view taken along line A-A of FIG. 11. FIG. 13 is an enlarged cross-sectional view of a region CX2 of FIG. 12.

Referring to FIG. 11, the semiconductor device 200 may include a plurality of active regions AC which are arranged to horizontally extend in a diagonal direction with respect to a first horizontal direction (an X direction) and a second horizontal direction (a Y direction) on a plane. A plurality of word lines WL may extend in parallel in the first horizontal direction (the X direction) across the plurality of active regions AC. A plurality of bit lines BL may extend in parallel in the second horizontal direction (the Y direction) intersecting with the first horizontal direction (the X direction), on the plurality of word lines WL. Each of the plurality of bit lines BL may be connected to the active region AC through a direct contact DC. A plurality of buried contacts BC may be disposed between two adjacent bit lines BL of the plurality of bit lines BL. A plurality of conductive landing pads LP may be disposed on the plurality of buried contacts BC. At least a portion of each of the plurality of conductive landing pads LP may be disposed to overlap a corresponding buried contact BC. A plurality of lower electrodes LE may be disposed apart from one another on the plurality of conductive landing pads LP. The plurality of lower electrodes LE may be connected to the plurality of active regions AC through the plurality of buried contacts BC and the plurality of conductive landing pads LP.

Referring to FIGS. 12 and 13, the semiconductor device 200 may include a substrate 210 including the plurality of active regions AC and a lower structure 220 formed on the substrate 210. The plurality of conductive regions 224 may pass through the lower structure 220 and may be connected to the plurality of active regions AC.

The substrate 210 may include a semiconductor element, such as Ge or Si, or a compound semiconductor such as SiC, GaAs, InAs, and InP. The substrate 210 may include a semiconductor substrate and at least one insulation layer formed on the semiconductor substrate or structures including at least one conductive region. The conductive region may include, for example, an impurity-doped well or an impurity-doped structure. A device isolation layer 212 defining the plurality of active regions AC may be formed in the substrate 210. The device isolation layer 212 may include oxide, nitride, or a combination thereof. In embodiments, the device isolation layer 212 may have various structures such as a shallow trench isolation (STI) structure.

In some embodiments, the lower structure 220 may include an insulation layer including silicon oxide, silicon nitride, or a combination thereof. In some other embodiments, the lower structure 220 may include various conductive regions, and for example, may include a wiring layer, a contact plug, a transistor, and an insulation layer insulating the elements from one another. The plurality of conductive regions 224 may include polysilicon, metal, conductive metal, metal silicide, or a combination thereof. The lower structure 220 may include the plurality of bit lines BL described above with reference to FIG. 10. Each of the plurality of conductive regions 224 may include the buried contact BC and the conductive landing pad LP described above with reference to FIG. 10.

An insulation pattern 226P including a plurality of openings 226H respectively overlapping the plurality of conductive regions 224 in a vertical direction (a Z direction) may be disposed on the lower structure 220 and the plurality of conductive regions 224. The insulation pattern 226P may include silicon nitride (SiN), silicon carbide nitride (SiCN), silicon boron nitride (SiBN), or a combination thereof.

A capacitor CP may be disposed on the plurality of conductive regions 224. The capacitor CP may include a lower electrode LE, a dielectric layer 260 covering the lower electrode LE, and an upper electrode UE which covers the dielectric layer 260 and is apart from the lower electrode LE with the dielectric layer 260 therebetween.

The insulation pattern 226P may be disposed adjacent to a lower end portion of each of the plurality of lower electrodes LE. Each of the plurality of lower electrodes LE may have a pillar shape which extends long in a direction distancing from the substrate 210 in the vertical direction (the Z direction) through the opening 226H of the insulation pattern 226P from an upper surface of the conductive region 224. In the drawings, a case where each of the plurality of lower electrodes LE has a pillar shape has been described for example, but aspects of the inventive concept re not limited thereto. For example, each of the plurality of lower electrodes LE may have a cross-sectional structure having a cup shape or a cylinder shape where a bottom portion is plugged.

The plurality of lower electrodes LE may be supported by a lower supporter 242P and an upper supporter 244P. The plurality of lower electrodes LE and the upper electrode UE may face each other with the dielectric layer 260 therebetween.

The upper supporter 244P may surround an upper end portion of each of the plurality of lower electrodes LE and may extend in parallel with the substrate 210. A plurality of holes 244H through which the plurality of lower electrodes LE respectively pass may be formed in the upper supporter 244P. An inner sidewall of each of the plurality of holes 244P formed in the upper supporter 244P may contact an outer sidewall of a corresponding lower electrode LE. An upper surface of each of the plurality of lower electrodes LE and an upper surface of the upper supporter 244P may be disposed on the same plane.

The lower supporter 242P may extend between the substrate 210 and the upper supporter 244P in parallel to the substrate 210 and may contact an outer sidewall of each of the plurality of lower electrodes LE.

Each of the lower supporter 242P and the upper supporter 244P may include SiN, SiCN, SiBN, or a combination thereof.

Each of the lower electrode LE and the upper electrode UE may include, for example, at least one of metals, such as doped polysilicon, ruthenium (Ru), titanium (Ti), tantalum (Ta), and tungsten (W), and metal nitrides such as titanium nitride (TiN), tantalum nitride (TaN), tungsten nitride (WN), chrome nitride (CrN), vanadium nitride (VN), molybdenum nitride (MoN), niobium nitride (NbN), titanium silicon nitride (TiSiN), titanium aluminum nitride (TiAlN), and tantalum aluminum nitride (TaAlN). In some embodiments, each of the lower electrode LE and the upper electrode UE may include a single layer or a multi-layer structure of the materials.

In some embodiments, the dielectric layer 260 may include a thin film which is formed by the methods S1, S21, S21A, S21B, S22, S22A, S22B, S30, S30A, S41, S41A, S42, S42A, and S43 of manufacturing the thin film described above with reference to FIGS. 1, 2A, 2B, 3A to 3D, 4A to 4D, 5A to 5C, 6A to 6C, 7A to 7C, 8A, and 8B. For example, the dielectric layer 260 may include a first atomic layer 10, second atomic layers 21 and 22, a third atomic layer 30, and/or fourth atomic layers 41 to 43.

In some embodiments, the dielectric layer 260 may include an additive ion 260A included in an atomic layer. The additive ion 260A may include one or more ions selected from among the second central ion BI, the third central ion CI, and the fourth central ion DI described above with reference to FIGS. 2A, 2B, 3A to 3D, 4A to 4D, 5A to 5C, 6A to 6C, 7A to 7C, 8A, and 8B. For example, the dielectric layer 260 may include a lattice consisting of the first central ion AI of the first precursor A, and the additive ion 260A may include the second central ion BI, the third central ion CI, and/or the fourth central ion DI each included in the lattice consisting of the first central ion AI. For example, the additive ion 260A may be included as a substitutional ion and/or an interstitial ion in the lattice of the dielectric layer 260.

In some embodiments, the dielectric layer 260 of the capacitor CP of the semiconductor device 200 according to an embodiment may be formed by the methods S1, S21, S21A, S21B, S22, S22A, S22B, S30, S30A, S41, S41A, S42, S42A, and S43 of manufacturing the thin film described above with reference to FIGS. 1, 2A, 2B, 3A to 3D, 4A to 4D, 5A to 5C, 6A to 6C, 7A to 7C, 8A, and 8B.

In some embodiments, the semiconductor device 200 according to an embodiment may include the additive ion 260A which is included as a substitutional ion and/or an interstitial ion in the lattice of the dielectric layer 260, and accordingly, stress may be applied to the lattice of the dielectric layer 260, thereby enhancing a ferroelectric characteristic and/or an anti-ferroelectric characteristic of the dielectric layer 260. Accordingly, the performance of the semiconductor device 200 may be enhanced.

Hereinabove, exemplary embodiments have been described in the drawings and the specification. Embodiments have been described by using the terms described herein, but this has been merely used for describing aspects of the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the following claims.

While aspects of the inventive concept has been particularly shown and described with reference to embodiments thereof, it will be understood that various changes in form and details may be made therein without departing from the spirit and scope of the following claims.

What is claimed is:

1. A method of manufacturing a thin film, the method comprising:
an operation of providing a substrate;
a first cycle including an operation of forming a first atomic layer on the substrate by using an atomic layer deposition (ALD) process using a first precursor; and
a second cycle including an operation of forming a second atomic layer on the first atomic layer by using an ALD process using the first precursor and a second precursor,
wherein the first atomic layer comprises a ferroelectric material layer or an anti-ferroelectric material layer,
the first precursor comprises a first central ion,
the second precursor comprises a second central ion, and
the second central ion is included as a substitutional ion in a lattice, in the second atomic layer, including the first central ion.

2. The method of claim 1, wherein the first central ion comprises one ion selected from among a hafnium (Hf) ion and a zirconium (Zr) ion, and
the second precursor comprises a cyclopentadienly ligand.

3. The method of claim 1, wherein a size of the second central ion is greater than or equal to a size of the first central ion.

4. The method of claim 3, wherein the second central ion comprises one ion selected from among a Ta⁺³ ion, a Mn⁺² ion, a V⁺² ion, a Nb⁺³ ion, a Sr⁺² ion, a Ba⁺² ion, a Ca⁺² ion, a Y⁺³ ion, a Sc⁺³ ion, a Cr⁺² ion, a Hf⁺⁴ ion, a Zr⁺⁴ ion, and a Co⁺² ion.

5. The method of claim 1, wherein a size of the second central ion is less than a size of the first central ion.

6. The method of claim 5, wherein the second central ion comprises one ion selected from among a Ti⁺³ ion, a Ni⁺³ ion, a Si⁴ ion, an Al⁺³ ion, and a Be⁺² ion.

7. The method of claim 1, wherein the second atomic layer comprises one selected from among an orthorhombic phase, a tetragonal phase, and a rhombohedral phase.

8. The method of claim 1, wherein a lattice strain of the second atomic layer to the first atomic layer is −5% to +10%, and
a volume strain of the second atomic layer to the first atomic layer is −20% to 30%.

9. The method of claim 1, wherein the second cycle comprises:
an operation of supplying the first precursor;
an operation of supplying the second precursor after the operation of supplying the first precursor; and
an operation of supplying an oxidant after the operation of supplying the second precursor.

10. A method of manufacturing a thin film, the method comprising:
an operation of providing a substrate;
a first cycle including an operation of forming a first atomic layer on the substrate by using an atomic layer deposition (ALD) process using a first precursor; and
a second cycle including an operation of forming a second atomic layer on the first atomic layer by using an ALD process using the first precursor and a second precursor,
wherein the first atomic layer comprises a ferroelectric material layer or an anti-ferroelectric material layer,
the first precursor comprises a first central ion,
the second precursor comprises a second central ion, and
the second central ion is included as an interstitial ion in a lattice, in the second atomic layer, including the first central ion.

11. The method of claim 10, wherein the first central ion comprises one ion selected from among a hafnium (Hf) ion and a zirconium (Zr) ion, and
the second precursor comprises an amine ligand.

12. The method of claim 10, wherein a size of the second central ion is greater than or equal to a size of the first central ion.

13. The method of claim 12, wherein the second central ion comprises one ion selected from among a Ta⁺³ ion, a Mn⁺² ion, a V⁺² ion, a Nb⁺³ ion, a Sr⁺² ion, a Ba⁺² ion, a Ca⁺² ion, a Y⁺³ ion, a Sc⁺³ ion, a Cr⁺² ion, a Hf⁺⁴ ion, a Zr⁺⁴ ion, and a Co⁺² ion.

14. The method of claim 10, wherein a pyrolysis temperature of the second precursor is lower than a pyrolysis temperature of the first precursor.

15. The method of claim 10, wherein a composition ratio of the second precursor is about 30 at % or less, in the second atomic layer.

16. The method of claim 10, wherein the second cycle comprises:
an operation of supplying the second precursor; and
an operation of pyrolyzing the second precursor.

17. A method of manufacturing a thin film, the method comprising:
a first cycle using an atomic layer deposition (ALD) process and including an operation of supplying a first precursor, an operation of performing purging, and an operation of supplying an oxidant; and
a second cycle using an ALD process and including an operation of supplying a second precursor, an operation of performing purging, and an operation of supplying the oxidant,
wherein the first precursor comprises a first central ion,
the second precursor comprises a second central ion, and
the first central ion comprises one of a hafnium (Hf) ion and a zirconium (Zr) ion, and
the second central ion is included as at least one, selected from among an interstitial ion and a substitutional ion, in a lattice including the first central ion.

18. The method of claim 17, wherein the second cycle further comprises, before the operation of supplying the oxidant, the operation of supplying the first precursor and the operation of performing purging,
the second precursor comprises a cyclopentadienly ligand, and
the second central ion is included as a substitutional ion in the lattice including the first central ion.

19. The method of claim 17, wherein the second precursor comprises an amine ligand,
the second cycle further comprises an operation of pyrolyzing the second precursor, and
the second central ion is included as an interstitial ion in the lattice including the first central ion.

20. The method of claim 19, wherein the second cycle further comprises an operation of supplying a third precursor and an operation of performing purging,
the third precursor comprises a third central ion,
the third precursor comprises a cyclopentadienly ligand, and
the third central ion is included as a substitutional ion in the lattice including the first central ion.
